(19) United States
(12) Patent Application Publication
(10) Pub. No.: US 2025/0133893 A1
(43) Pub. Date: Apr. 24, 2025

(54) Wiring Substrate, Electronic Element and Electronic Apparatus

(71) Applicants: Hefei BOE Ruisheng Technology Co., Ltd., Hefei, Anhui (CN); BOE Technology Group Co., Ltd., Beijing (CN)

(72) Inventors: Hai TANG, Beijing (CN); Wei HAO, Beijing (CN); Yiding SUN, Beijing (CN); Yongle FANG, Beijing (CN); Liang GAO, Beijing (CN); Xiaolin GENG, Beijing (CN)

(21) Appl. No.: 18/689,874

(22) PCT Filed: Jan. 19, 2023
(86) PCT No.: PCT/CN2023/073169

§ 371 Date: Mar. 7, 2024

(51) Int. Cl. H10H 29/85; H01L 25/075; H10H 29/80

(52) U.S. Cl. CPC H10H 29/857; H01L 25/0753; H10H 29/962

(57) ABSTRACT

A wiring substrate, an electronic element and an electronic apparatus is provided according to the disclosure, the wiring substrate includes: a base substrate; connection lines located on the substrate, wherein at least two connection lines are configured to transmit different signals; a plurality of pads, wherein any two pads are distributed at intervals, and the pads include first pads; a first pad group composed of at least three first pads; wherein the connection lines include a first type of connection line, which includes a plurality of branch portions, different branch portions are connected with different first pads, and any two branch portions are arranged at intervals.

### CROSS-REFERENCE TO RELATED APPLICATION

The present application is a U.S. National Phase Entry of International Application No. PCT/CN2023/073169 having an international filing date of Jan. 19, 2023, the entire content of which is hereby incorporated by reference.

### TECHNICAL FIELD

The disclosure relates to the field of display technology, in particular to a wiring substrate, an electronic element and an electronic apparatus.

### BACKGROUND

In recent years, the backlight and display technology based on Mini LED (Micro LED) has developed rapidly. Compared with traditional liquid crystal products, Micro LED products may achieve local dimming within a smaller scale, better brightness uniformity, higher color contrast and thinner product appearance. Their display effect is basically the same as that of products of organic light emitting devices, but the cost is only 60% of that of organic light emitting devices, and the product life is greatly improved. Based on the above advantages, micro light emitting devices have developed rapidly in recent years and have a good market prospect.

### SUMMARY

The specific solution of the wiring substrate, the electronic element and the electronic apparatus according to the present disclosure is as follows.

In a first aspect, an embodiment of the present disclosure provides a wiring substrate, including:
a base substrate;
connection lines located on the substrate, wherein at least two of the connection lines are configured to transmit different signals;
a plurality of pads, wherein any two of the pads are distributed at intervals, and the pads include first pads;
a first pad group composed of at least three of the first pads;
wherein the connection lines include a first type of connection line, the first type of connection line includes a plurality of branch portions, different branch portions are connected with different first pads, and any two branch portions are arranged at intervals.

In some embodiments, in the aforementioned wiring substrate according to an embodiment of the present disclosure, the plurality of branch portions of a same first type of connection line extend along a same direction, with an extension length of at least 400 μm.

In some embodiments, in the aforementioned wiring substrate according to the embodiment of the present disclosure, the plurality of branch portions of the same first type of connection line, and the plurality of the first pads respectively connected with the plurality of branch portions are arranged along a first direction, the plurality of branch portions extend along a second direction, and the first direction and the second direction have an included angle.

In some embodiments, in the aforementioned wiring substrate according to an embodiment of the present disclosure, the connection lines further include a second type of connection line, which is configured to connect two of the first pads in one of first pad groups, and an orthographic projection of the second type of connection line on the substrate is within an orthographic projection of a region where the first pad group is located on the substrate.

In some embodiments, in the aforementioned wiring substrate according to an embodiment of the present disclosure, two of the first pads connected by the second type of connection line are arranged along a first direction, and the second type of connection line extends along the first direction.

In some embodiments, in the aforementioned wiring substrate according to an embodiment of the present disclosure, the pads further include second pads, the wiring substrate further includes a second pad group composed of two of the second pads, and the connection lines further include a third type of connection line, which is configured to be connected at least to one of the first pads, and a length of the third type of connection line is at least 400 μm.

In some embodiments, in the aforementioned wiring substrate according to an embodiment of the present disclosure, a difference between line widths of any connection line at various places is less than 15% in a direction perpendicular to an extension direction of the connection line.

In some embodiments, in the aforementioned wiring substrate according to an embodiment of the present disclosure, a difference between line widths of any two of the connection lines is less than 15% in a direction perpendicular to an extension direction of the connection lines.

In some embodiments, in the aforementioned wiring substrate according to an embodiment of the present disclosure, the wiring substrate further includes signal lines, wherein each of the signal lines is coupled to at least one of the connection lines.

In some embodiments, in the aforementioned wiring substrate according to an embodiment of the present disclosure, a difference between a line width of a signal line in a direction perpendicular to an extension direction of the signal line and a line width of a connection line coupled to the signal line in a direction perpendicular to an extension direction of the connection line is less than 15%.

In some embodiments, in the aforementioned wiring substrate according to an embodiment of the present disclosure, the pads further include second pads, the wiring substrate further includes a second pad group composed of two of the second pads, and the connection lines further include a fourth type of connection line, which is configured to connect one of the second pads with a signal line.

In some embodiments, in the aforementioned wiring substrate according to an embodiment of the present disclosure, the signal line and the connection line coupled to the signal line are of an integral structure.

In some embodiments, in the aforementioned wiring substrate according to an embodiment of the present disclosure, any two adjacent branch portions corresponding to a same first pad group have a first spacing in a direction perpendicular to an extension direction of the branch portions, a minimum spacing between two adjacent signal lines is a second spacing, and a ratio of the first spacing to the second spacing is between 0.9 and 1.1.

On the other hand, an embodiment of the present disclosure provides an electronic element connected to a pad of the aforementioned wiring substrate according to an embodiment of the present disclosure.

In some embodiments, in the aforementioned electronic element according to an embodiment of the present disclosure, the electronic element includes a functional layer and a pin located on the functional layer, wherein the pin includes a recess portion arching towards the functional layer, the recess portion gradually decreases in a direction close to the functional layer, and a ratio of an area of an orthographic projection of an end face of the recess portion close to the functional layer on the functional layer to an area of an orthographic projection of the pin on the functional layer is less than or equal to 30%.

In some embodiments, in the aforementioned electronic element according to an embodiment of the present disclosure, there is a first distance between a center of an orthographic projection of the recess potion on the functional layer and a center of the orthographic projection of the pin on the functional layer, and a ratio of the first distance to a radial length of the pin is less than 20%.

In some embodiments, in the aforementioned electronic element according to an embodiment of the present disclosure, a connection structure located at a side of the pin away from the functional layer is further included, the connection structure fills the recess portion, and a thickness of the connection structure is greater than or equal to 15 μm and less than or equal to 25 μm.

In some embodiments, in the aforementioned electronic elements according to an embodiment of the present disclosure, the electronic element includes a micro drive chip connected to the first pad group.

On the other hand, an embodiment of the present disclosure provides an electronic apparatus, which includes the aforementioned wiring substrate according to an embodiment of the present disclosure and the aforementioned electronic element according to an embodiment of the present disclosure.

In some embodiments, in the aforementioned electronic apparatus according to an embodiment of the present disclosure, a micro light emitting device connected to the second pad group is also included.

### BRIEF DESCRIPTION OF DRAWINGS

FIG. 1 is a schematic diagram of a formation principle of intermetallic compounds.

FIG. 2 is a schematic diagram of a pad trace according to an embodiment of the present disclosure.

FIG. 3 is a schematic diagram of another pad trace according to an embodiment of the present disclosure.

FIG. 4 is a physical view of welding back inspection of the pad trace shown in FIG. 2.

FIG. 5 is a physical view of welding back inspection of the pad trace shown in FIG. 3.

FIG. 6 is a schematic diagram of a wiring substrate according to an embodiment of the present disclosure.

FIG. 7 is a schematic enlarged view of the region Z1 in FIG. 6.

FIG. 8 is another schematic enlarged view of the region Z1 in FIG. 6.

FIG. 9 is a schematic enlarged view of the region Z2 in FIG. 6.

FIG. 10 is another schematic enlarged view of the region Z2 in FIG. 6.

FIG. 11 is a physical view of a welding back inspection of the first pad group in the Z3 region of FIG. 7.

FIG. 12 is a schematic diagram of another pad trace according to an embodiment of the present disclosure.

FIG. 13 is a schematic diagram of an electronic element according to an embodiment of the present disclosure.

FIG. 14 is a picture of an electronic element according to an embodiment of the present disclosure.

FIG. 15 is a cross-sectional view along a direction I-II in FIG. 14.

FIG. 16 is another picture of an electronic element according to an embodiment of the present disclosure.

FIG. 17 is a cross-sectional view along a direction IIII-IV in FIG. 16.

FIG. 18 is another picture of an electronic element according to an embodiment of the present disclosure.

FIG. 19 shows a sealing-off phenomenon caused by an excessive voidage.

FIG. 20 is a curve showing a relationship between a voidage and a welding flux amount.

FIG. 21 is a schematic diagram of an electronic apparatus according to an embodiment of the present disclosure.

### DETAILED DESCRIPTION

In order to make objectives, technical solutions and advantages of the embodiments of the present disclosure more clear, the technical solutions of the embodiments of the present disclosure will be clearly and completely described below with reference to the drawings of the embodiments of the present disclosure. It should be noted that in order to make objectives, technical solutions and advantages of the embodiments of the present disclosure more clear, the technical solutions of the embodiments of the present disclosure will be clearly and completely described below with reference to the drawings of the embodiments of the present disclosure. It should be noted that in the drawings, thicknesses of layers, films, panels, regions and the like are enlarged for clarity. An exemplary implementation is described in the present disclosure with reference to a cross-sectional view as a schematic diagram of the idealized implementation. In this way, deviations between the shape of the drawing and a result of, for example, manufacturing techniques and/or tolerances will be anticipated. Thus, the implementation described in the present disclosure should not be construed as being limited to the specific shape of the region as shown in the present disclosure, but include deviations in shape caused by for example manufacturing. For example, regions illustrated or described as flat may typically have rough and/or non-linear characteristics; and the sharp corners shown may be round, etc. Thus, the regions shown in the figures are schematic in nature and their dimensions and shapes are not intended to illustrate the exact shape of the regions and do not reflect true proportions, but are intended only to illustrate the contents of the present disclosure. Moreover, same or similar elements or elements having same or similar functions are denoted by same or similar reference numerals throughout the descriptions. In order to keep following description of the embodiments of the present disclosure clear and concise, detailed description of known functions and known components are omitted in the present disclosure.

Unless otherwise defined, technical terms or scientific terms used herein shall have an ordinary meanings understood by those with ordinary skills in the art to which the present disclosure pertains. The “first”, “second” and similar terms used in specification and claims of the present disclosure do not indicate any order, quantity, or importance, but are used only for distinguishing different components. “Include”, “contain”, or a similar word mean that elements or objects appearing before the word cover elements or objects listed after the words and their equivalents, but do not exclude other elements or objects. “Connect”, “connected”, or a similar term is not limited to a physical or mechanical connection, but may include an electrical connection, whether direct or indirect. “Inner”, “outer”, “upper”, “lower”, etc., are used to represent relative position relations, and when an absolute position of a described object is changed, the relative position relation may also be correspondingly changed.

In the following description, when an element or a layer is referred to as being “on” or “connected to” another element or layer, the element or layer may be directly on or directly connected to the other element or layer, or there may be an intermediate element or layer. When an element or a layer is referred to as being “arranged at” a side of another element or layer, the element or layer may be directly at a side or directly connected to the element or layer, or there may be an intermediate element or layer. However, when an element or layer is referred to as being “directly on” or “directly connected” to another element or layer, there is no intermediate element or layer. The term “and/or” includes any and all combinations of one or more related listed items.

Electronic elements, such as micro driver chips, micro light emitting devices, capacitors and resistors, are generally bound and connected with pads on the backplane by using welding flux through a welding process, and the stability of products is directly related to the welding quality. In the reflow welding process, the intermetallic compound (IMC) is generated by the reaction between the welding flux and the pad, which achieves the welding of electronic elements. Welding flux may be pre-arranged on a surface of a pin of an electronic element or a surface of a pad, and welding flux is generally SnAg alloy, SnAgCu alloy, or other tin alloy materials.

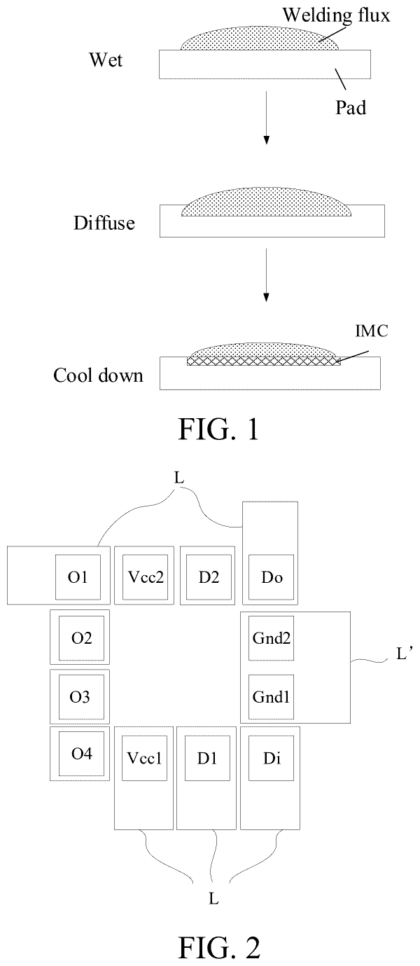

As shown in FIG. 1, intermetallic compound (IMC) is an important evidence of forming a good welding flux joint. When the welding flux is heated to the melting point, it will melt, and the melted welding flux will wet the pad. There is an inter-diffusion between the welding flux metal and the metal in the pad base metal to form an intermetallic compound (IMC) layer. In the case that the backplane allows visible light to pass through, it may be judged whether a welding defect (such as false welding) occurs by means of back detection.

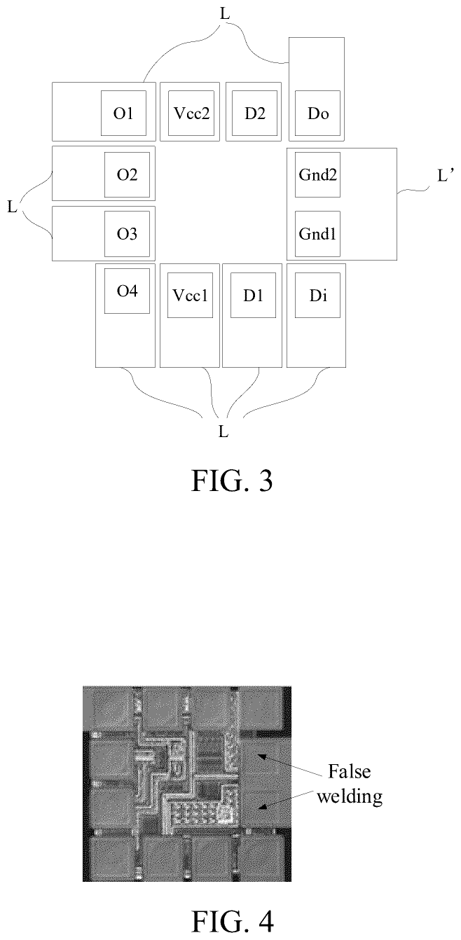

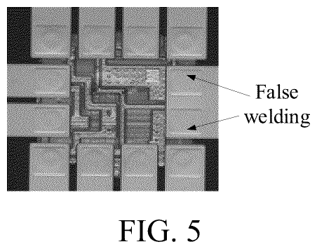

The reliability of welding is related to the pin design of electronic elements, the pad design and the trace design of the wiring substrate. The wiring substrate includes a first pad group arranged in an array of x rows and y columns, and a plurality of second pad groups arranged in an array of m rows and n columns. Any two adjacent first pad groups in a column of first pad groups are cascaded, each first pad group has p output pads out, and p adjacent second pad groups in the same column are respectively connected with various output pads out in the same first pad group. If p cannot be divisible by m, at least one output pad out of at least one first pad group is an island; and in addition, the second data pad D2 and the second power supply pad Vcc2 of the last stage of the first pad group will also become islands because there is no cascade relationship therebetween. The inventors have discovered that if part of pads (e.g. O2, O3, O4, Vcc2, D2 shown in FIG. 2) in the pad group are not connected to any one of the traces L/L′, it is an island, and the rest pads in this pad group are respectively connected to the traces L/L′. In this case, during the reflow welding process, there are differences in temperatures on the surfaces of different pads, which may affect the uniformity of welding. For example, there is a time difference in the completion of welding of different pads, which may easily lead to over-welding or false welding in part of the pads. In addition, in the pad group shown in FIG. 2 and FIG. 3, in order to simplify the wiring, a plurality of pads (e.g. Gnd1, Gnd2) receiving the same signal are connected to the same trace L′, and compared to a case that the trace L is connected to one pad, there will also be differences in temperatures on the surfaces of different pads during the reflow welding process, which results in uneven welding, overwelding or poor false welding, as shown in FIG. 4 and FIG. 5. In addition, through the verification of welding process, the incidence of welding defects in FIG. 2 is 1.2318%, and the incidence of welding defects in FIG. 3 is 0.3043%. In order to ensure the quality and yield, it is usually stipulated that the incidence of welding defects is less than 0.3%, but the incidence of welding defects in FIG. 2 and FIG. 3 is higher than 0.3000%, that is, the welding yield is low.

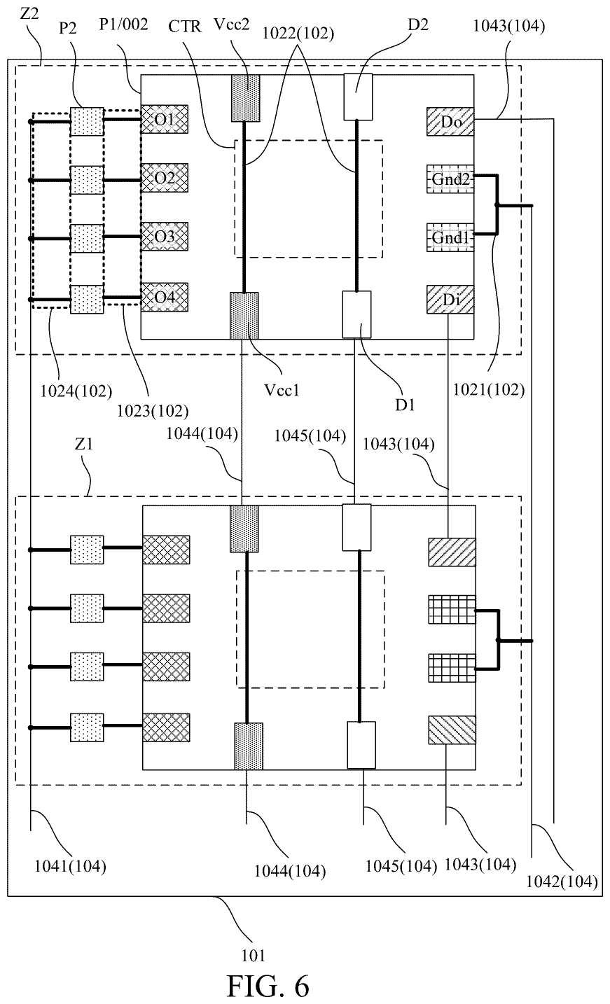

In order to solve the above technical problems existing in the related art, an embodiment of the present disclosure provides a wiring substrate, as shown in FIG. 6 to FIG. 10, which includes: a base substrate 101, connection lines 102, a plurality of pads 103, a first pad group P1.

The base substrate 101 is optionally a substrate allowing transmission of visible light, for example, glass, quartz, plastic, polyimide and other materials.

The connection lines 102 are located on the substrate 101, at least two connection lines 102 are configured to transmit different signals.

Any two of the pads 103 are distributed at intervals. In some embodiments, the pad 103 and the connection line 102 and/or the signal line 104 are of an integral structure, the pad 103 is a region of the connection line 102 and/or the signal line 104 exposed by an opening O of the insulation layer, and the pad 103 is used for connecting with a pin of an electronic element. Optionally, the pads 103 include a first pad 1031, such as a first output pad O1, a second output pad O2, a third output pad O3, a fourth output pad O4, a first ground pad Gnd1, a second ground pad Gnd2, an address pad Di, a relay pad Do, a first data pad D1, a second data pad D2, a first power supply pad Vcc1, and a second power supply pad Vcc2. In some embodiments, address pads Di may be utilized to receive address signals, and address information of the micro drive chip is configured according to an address signal and a relay signal is generated; the relay signal may be used as an address signal of the next stage micro driver chip; the first data pad D1 and the second data pad D2 are used for receiving drive data, which includes drive information and address verification information. When the address verification information is matched with the address information, a drive current corresponding to at least one light emitting unit connected with the micro drive chip is generated according to the drive information, and an output pad (for example, a first output pad O1, a second output pad O2, a third output pad O3, a fourth output pad O4) of the micro drive chip is controlled to form an electrical path with the corresponding light emitting unit, wherein the drive current flows in the electrical path.

The first pad group P1 is composed of at least three first pads 1031. As shown in FIGS. 6 to 10 specifically, there are altogether 12 first pads 1031, i.e., a first output pad O1, a second output pad O2, a third output pad O3, a fourth output pad O4, a first ground pad Gnd1, a second ground pad Gnd2, an address pad Di, a relay pad Do, a first data pad D1, a second data pad D2, a first power supply pad Vcc1, and a second power supply pad Vcc2 to form a first pad group P1.

The connection lines 102 include a first type of connection lines 1021, a first type of connection line 1021 includes a plurality of branch portions 211, and different branch portions 211 correspond to different first pads (e.g. the first ground pad Gnd1, the second ground pad Gnd2), and any two branch portions 211 are arranged at intervals.

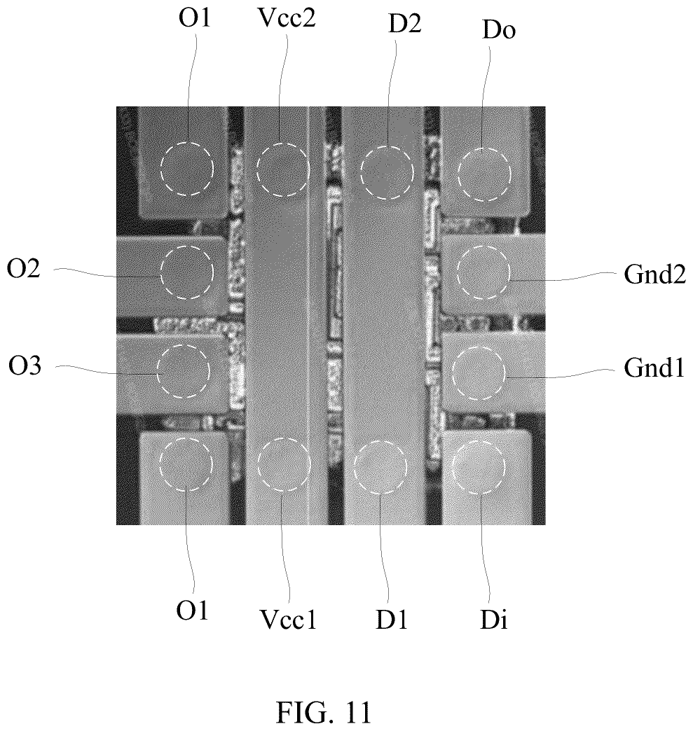

In the aforementioned wiring substrate according to an embodiment of the present disclosure, different branch portions 211 are used to independently lead out different first pads (for example, the first ground pad Gnd1 and the second ground pad Gnd2), so that the difference between metal proportions of different first pads (i.e., a proportion of a width of the first pad to a line width of its corresponding connection line 102 or signal line 104) is reduced, and the welding is more uniform during the reflow welding process, which may effectively improve welding defects. It has been verified that the incidence of welding defects in this disclosure is only 9*10⁻⁶, which is far less than the incidence standard 0.3% of welding defects, showing excellent welding characteristics, and no concentrated welding defect is found in back inspection, as shown in FIG. 11.

It is noted that with the present disclosure, the welding yield of products with intermetallic compound (IMC) layers may be improved, and for products without intermetallic compound (IMC) layers, the material of the pads has poor corrosion resistance or welding fluxability, and welding flux (such as welding flux paste) will diffuse along the traces to form a welding influence region; if a design of the connection of two pads is adopt, crosstalk will occur in the welding reaction and over-welding phenomenon will occur; and by adopting the design of separate traces of the two pads in the present disclosure, the problem of mutual influence of welding may be effectively solved.

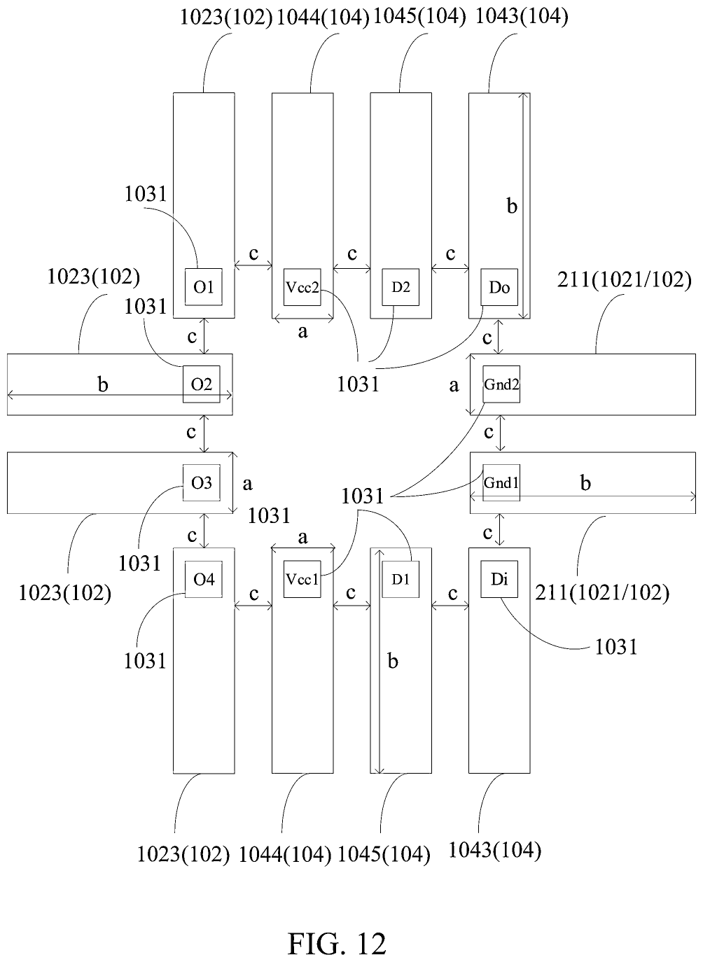

In some embodiments, in the aforementioned wiring substrate according to an embodiment of the present disclosure, as shown in FIG. 12, in order to improve the welding yield, the wiring corresponding to the first pad 1031 may be designed, for example, a plurality of branch portions 211 of the same first type of connection line 1021 may be arranged to extend along the same direction, and an extension length b is at least 400 μm. With continued reference to FIG. 12, in order to improve the welding yield, in the present disclosure, an extension length b of the connection line 102 or signal line 104 corresponding to any first pad 1031 may be set to be greater than or equal to 400 μm. A difference between the line widths a of any connection line 102 or signal line 104 at various places in a direction perpendicular to its extension direction is within 15% (e.g. 10%), a difference between the line widths a of any two connection lines 102 or signal lines 104 in a direction perpendicular to their extension direction is within 15% (e.g. 10%), and a difference c between spacings of adjacent connection lines 102 or signal lines 104 is within 15%. The difference is less than 15% (for example, 10%).

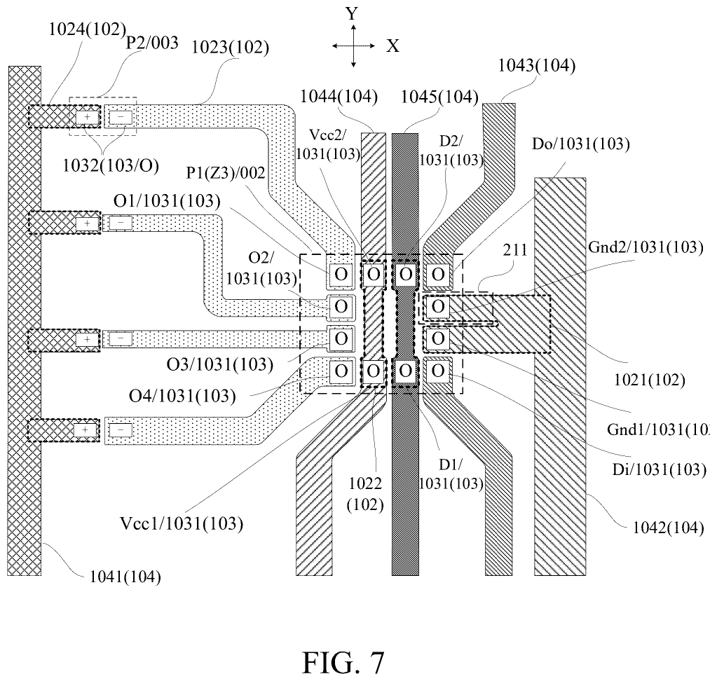

In some embodiments, in the aforementioned wiring substrate according to an embodiment of the present disclosure, as shown in FIGS. 7 to 10, in order to simplify the wiring design, a plurality of branch portions 211 of the same first type of connection line 1021 and first pads (for example, a first ground pad Gnd1 and a second ground pad Gnd2) corresponding to the plurality of branch portions 211 may be respectively arranged along a first direction Y and the plurality of branch portions 211 all extend along a second direction X, and the first direction Y and the second direction X have an included angle, for example, the first direction Y is perpendicular to the second direction X.

In some embodiments, in the aforementioned wiring substrate according to an embodiment of the present disclosure, as shown in FIGS. 6 to 10, the connection lines 102 may further include a second type of connection line 1022 which is configured to connect two first pads 1031 (for example, the first power supply pad Vcc1 and the second power supply pad Vcc2, or the first data pad D1 and the second data pad D2) in the first pad group P1, and an orthographic projection of the second type of connection line 1022 on the base substrate 101 is located within an orthographic projection of a region where the first pad group P1 is located on the base substrate 101, so as to achieve transmission of power supply signals or data signals and the like through the internal trace in a region where the first pad group P1 is located, so that an internal space of a region where the first pad group P1 is located is fully utilized.

In some embodiments, in the aforementioned wiring substrate according to an embodiment of the present disclosure, as shown in FIGS. 7 to 10, two first pads 1031 (e.g. a first power supply pad Vcc1 and a second power supply pad Vcc2, or a first data pad D1 and a second data pad D2) connected by the second type of connection line 1022 may be arranged along the first direction Y, and accordingly, to simplify wiring, the second type of connection line 1022 extends along the first direction Y.

In some embodiments, in the aforementioned wiring substrate according to an embodiment of the present disclosure, as shown in FIGS. 6 to 10, the pads 103 may further include a second pad 1032 (e.g. a positive pad “+”, a negative pad “−”), the wiring substrate further includes a second pad group P2, which is composed of two second pads 1032 (e.g. the positive pad “+”, the negative pad “−”), and the connection lines 102 further include a third type of connection line 1023 which is configured to be connected to at least one first pad 1031 (e.g. a first output pad O1, a second output pad O2, a third output pad O3, a fourth output pad O4); optionally in a case where the micro drive chip connected by the first pad group P1 provides a drive current to a lamp region, a third type of connection line 1023 connects a first pad 1031 (e.g. a first output pad O1, a second output pad O2, a third output pad O3, a fourth output pad O4) and a second pad 1032 (e.g. a negative pad), or in a case where the first pad group P1 is not connected to the lamp region, the third type of connection line 1023 may connect a first pad 1031 and not connect the second pad 1032; the third type of connection line 1023 independently leads out the first pad 1031 (e.g. the first output pad O1, the second output pad O2, the third output pad O3, or the fourth output pad O4) to which it is connected, thus avoiding the island design of the first pad 1031 (e.g. the first output pad O1, the second output pad O2, the third output pad O3, or the fourth output pad O4) and facilitating the improvement of the welding yield. In some embodiments, in order to further improve the welding yield, a length of a third type of connection line 1023 may be set to be at least 400 μm.

It should be noted that FIGS. 7 to 10 in the present disclosure show only one positive electrode pad “+” and one negative electrode pad “−” in one lamp region, and the positive electrode pad “+” and the negative electrode pad “−” may be connected with the pins of a micro light emitting device. In some embodiments, one lamp region may also have a plurality of positive pads “+” and a plurality of negative pads “−” such that a plurality of micro light emitting devices may be connected in parallel and/or in series in one lamp region. In addition, FIGS. 7 to 10 show that the first pad group P1 has four output pads O1 to O4, and in some embodiments, one first pad group P1 may also have three, five or other numbers of output pads, which are not limited here.

In some embodiments, in the aforementioned wiring substrate according to an embodiment of the present disclosure, as shown in FIGS. 6 to 10, the signal lines 104 may also be included, and each signal line 104 is coupled to at least one connection line 102. Optionally, the signal line 104 and the connection line 102 coupled thereto are of an integral structure to simplify the wiring design.

In some embodiments, as shown in FIGS. 6-10, the signal line 104 may include a first voltage line 1041, and the connection line 102 may also include a fourth type of connection line 1024 which is configured to connect a second pad 1032 (e.g., a positive pad “+”) in the second pad group P2 with a signal line (e.g., a first voltage line 1041) to provide a drive voltage for the micro light emitting device in the lamp region. In some embodiments, a plurality of first pad groups P1 are cascaded along a first direction Y, and various second pad groups P2 to which the plurality of cascaded first pad groups P1 are connected may be connected to the same first voltage line 1041; optionally, the fourth type of connection lines 1024 connecting the same first voltage line 1041 with various second pad groups P2 extend along the second direction X, and there is no overlapping between the various fourth type of connection lines 1024, which is beneficial for achieving a single layer trace design of the wiring substrate.

It can be understood that the first type of connection line 1021, the second type of connection line 1022, the third type of connection line 1023, and the fourth type of connection line 1024 are not overlapped with each other, which is beneficial for achieving the single layer trace design of the wiring substrate.

In some embodiments, as shown in FIGS. 6-10, the signal line 104 may also include a ground signal line 1042 that is electrically connected to at least one ground pad (e.g., a first ground pad Gnd1, a second ground pad Gnd2) through a branch 211 of the first type of connection line 1021. Exemplarily, the ground signal line 1042 is electrically connected to the first ground pad Gnd1 and the second ground pad Gnd2 of each of the first pad groups P1 arranged in cascade respectively to provide a ground signal for the ground pads. The ground signal line 1042 extends along the first direction Y, is located outside the first pad group P1, and is close to the first ground pad Gnd1 and the second ground pad Gnd2. Since the ground signal line 1042 needs to be electrically connected to at least one ground pad (e.g. the first ground pad Gnd1, the second ground pad Gnd2) of each first pad group P1, the ground signal line 1042 is arranged closest to the ground pad (e.g. the first ground pad Gnd1, the second ground pad Gnd2), which may facilitate the electrical connection between the ground signal line 1042 and the ground pad (e.g. the first ground pad Gnd1, the second ground pad Gnd2) and avoid overlapping with other signal lines.

In some embodiments, as shown in FIGS. 6-10, the signal lines 104 may also include an address signal line 1043 including a plurality of sub-segments arranged at intervals, and a region where the sub-segments are exposed by the opening O of the insulation layer may serve as an address pad Di, and a relay pad Do. In the plurality of first pad groups P1 arranged in cascade, the address pad Di of the first stage first pad group P1 is integrally arranged with the first sub-segment, the relay pad Do of the n-th (n is a positive integer) stage first pad group P1 and the address pad Di of the (n+1) stage first pad group P1 belong to the same sub-segment, and the relay pad Do of the last stage first pad group P1 is integrally arranged with the last sub-segment. The address pad Di is capable of receiving an address signal and configuring the address information of the first pad group Di according to the address signal. The logic control module CTR of the micro drive chip generates a relay signal according to the received address information, and the relay signal is outputted by the relay pad to the address pad Di of the next stage first pad group P1 as the address signal of the next stage first pad group P1.

In some embodiments, as shown in FIGS. 6-10, the signal lines 104 may also include a second voltage line 1044 including a plurality of sub-segments, wherein one of the sub-segments is electrically connected to a first power supply pad Vcc1 in the first stage first pad group P1, and the rest sub-segments connect a second power supply pad Vcc2 in the n-th (n is a positive integer) stage first pad group P1 with a first power supply pad Vcc1 of the (n+1)-th stage first pad group P1. The second voltage line 1044 supplies a voltage to each of the first pad groups P1 so that it can operate normally.

In some embodiments, as shown in FIGS. 6-10, the signal lines 104 may also include a test signal line 1045 including a plurality of sub-segments, wherein one of the sub-segments is electrically connected to the first data pad D1 in the first stage first pad group P1, and the rest sub-segments connect the second data pad D2 in the n-th (n is a positive integer) stage first pad group P1 with the first data pad D1 in the (n+1) stage first pad group P1. The test signal line 1045 may provide a test signal for each of the first pad groups P1 for testing whether there is an abnormality in the lamp region to which all of the first pad groups P1 are electrically connected.

In some embodiments, the test signal line 1045 is configured to be capable of transmitting the test signal and the drive data in a time-sharing manner, and the test signal line 1045 and the second voltage line 1044 respectively adopt different signal lines, which may simplify the circuit structure of the region where the first pad group P1 is located, without providing a power regulation circuit (the power regulation circuit is used for generating the drive voltage based on a direct current component in the power supply signal and generating a drive data based on a modulation component in the power supply signal) in the region where the first pad group P1 is located, which is thus beneficial for a reduction of an area of the region (equivalent to the micro drive chip) where the first pad group P1 is located. In addition, this arrangement may also simplify the external circuit structure, which may not only avoid providing a modulation circuit that modulates the drive voltage and the drive data into power line carrier communication, but also reduce the quality requirement on the drive voltage.

In some embodiments, in the aforementioned wiring substrate according to an embodiment of the present disclosure, in order to improve the welding yield, the difference between a line width of the signal line 104 in a direction perpendicular to its own extension direction and a line width of the connection line 102 coupled to the signal line 104 in a direction perpendicular to its own extension direction may be set to be less than 15%.

In some embodiments, in the aforementioned wiring substrate according to an embodiment of the present disclosure, any two adjacent branch portions 211 corresponding to the same first pad group P1 have a first spacing in a direction perpendicular to their extension direction, and the minimum spacing between the two adjacent signal lines 104 is a second spacing. In order to save wiring space and avoid short circuit between the adjacent branch portions 211 or the adjacent signal lines 104, a ratio of the first spacing to the second spacing may be set to be between 0.9 and 1.1 (e.g. 0.9, 1.0, 1.1, etc.).

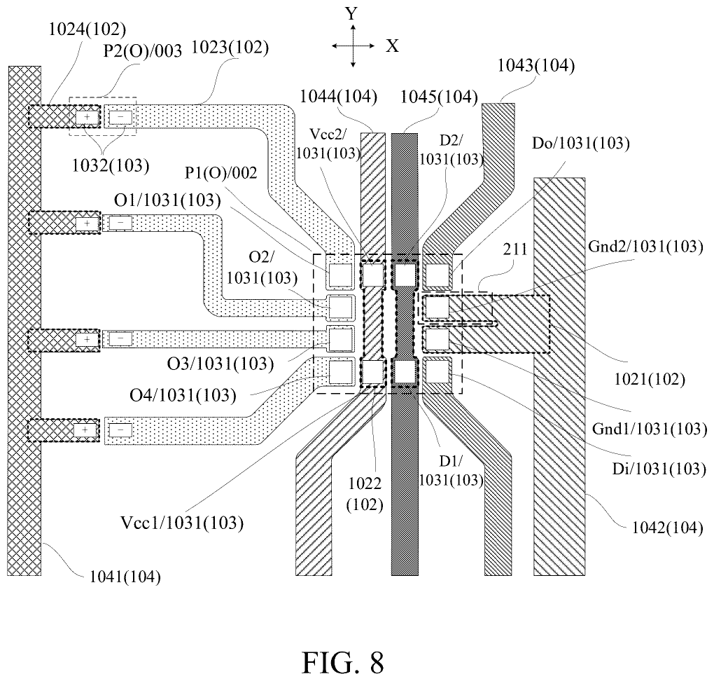

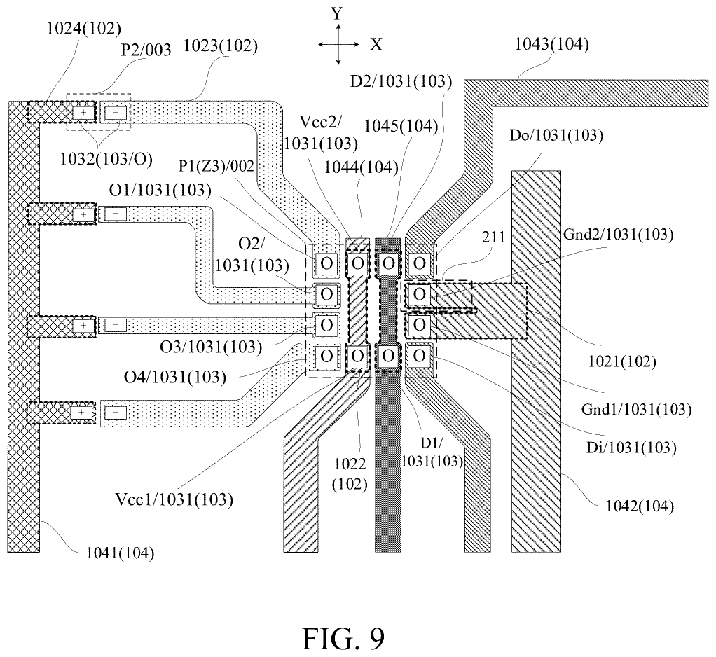

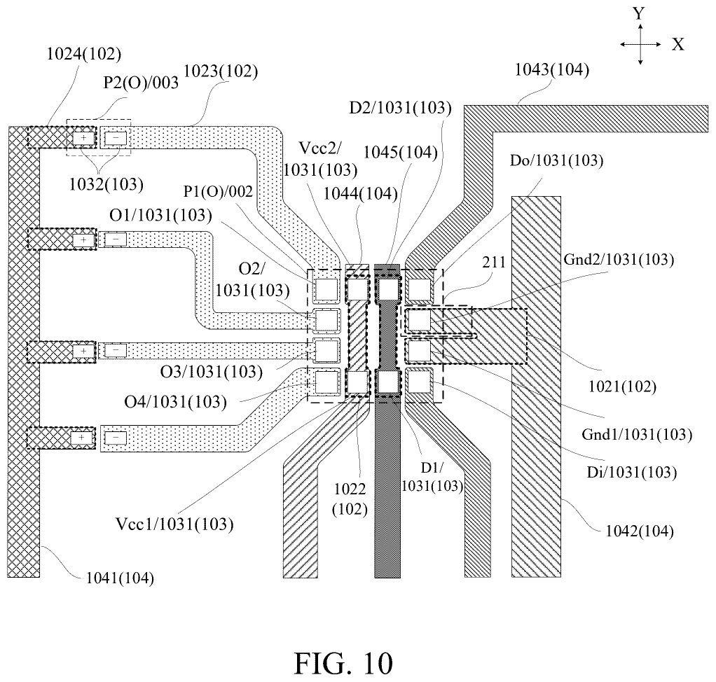

In some embodiments, in the aforementioned wiring substrate according to an embodiment of the present disclosure, as shown in FIG. 7 and FIG. 9, one opening O of the insulation layer may expose a pad 103, or as shown in FIG. 8 and FIG. 10, one opening O of the insulation layer may also expose a first pad group P1 or a second pad group P2.

Based on the same inventive concept, an embodiment of the present disclosure provides an electronic element which is connected to the pad of the aforementioned wiring substrate according to an embodiment of the present disclosure. In some embodiments, the electronic element includes a micro driver chip which is coupled to the first pad group P1.

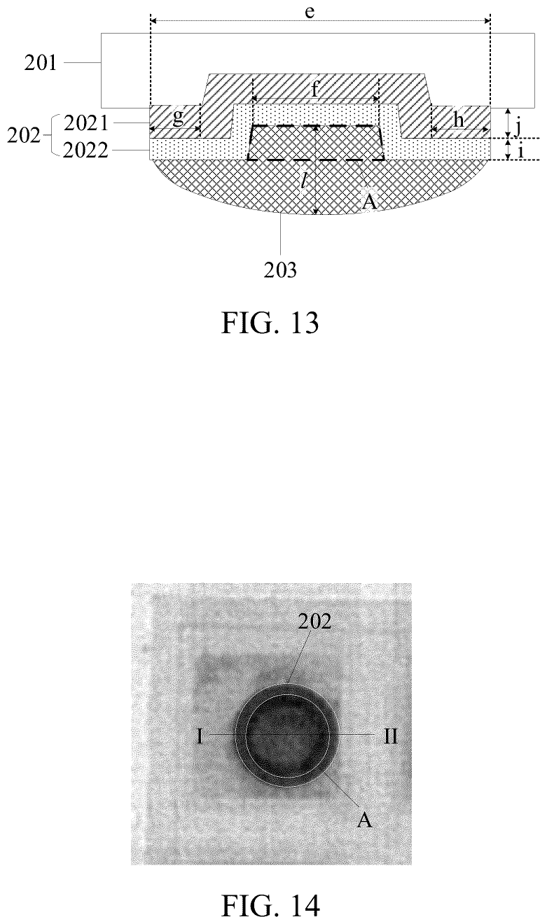

Optionally, as shown in FIG. 13, the electronic element includes a functional layer 201 and a pin 202 located on the functional layer 201. Limited by the structural characteristics of the pin 202, the pin 202 needs to be designed as a step shape (i.e., the pin 202 includes a recess portion A arching towards the functional layer 201), and in order to conduct the top of the step to the internal circuit system of the device, a sufficient pin area is ensured on the bottom of the step to meet the pushing and pulling force requirements on the electronic element after welding, and the recess portion A gradually decreases in a direction Z close to the functional layer 201. In some embodiments, the functional layer 201 includes a substrate base material such as sapphire, silicon carbide (SiC), and a semiconductor material layer located on the substrate base material. The signal interaction between the electronic element and the circuit layer is introduced into the electronic element by the pin 202. Welding flux such as welding flux paste may be preset on the surface of the pin 202, and the welding flux on the pin 202 is combined with the pad through welding to achieve circuit conduction. The pin 202 may be of a single-layer structure or a multi-layer structure, and the material of the pin 202 may include copper. FIG. 13 shows that the pin 202 includes a first conductive layer 2021 and a second conductive layer 2022, wherein a material of the first conductive layer 2021 is copper, and a material of a second conductive layer 2022 is nickel. A left step width g of the first conductive layer 2021 is greater than 10 μm, and a right step width h of the first conductive layer 2021 is greater than 10 μm. A thickness j of the first conductive layer 2021 is greater than or equal to 3 μm and less than or equal to 10 μm, and a thickness j of the second conductive layer 2022 is greater than or equal to 1 μm and less than or equal to 5 μm.

During the reflow welding process, the welding flux originally preset on the pins of electronic elements will move to the surface of the pad. The stronger the welding fluxability of the materials used in the pad, the farther the welding flux moves. During the reflow welding process, the welding flux tends to transfer from the pin 202 of the electronic element to the pad. The stronger the welding fluxability of the pad, for example, the pad material is changed from an alloy material containing copper and nickel to a material containing nickel and gold, the easier the welding flux diffuses to the pad. The welding flux is originally present on the surface of the pin 202 towards the pad, and due to the existence of the recess portion A in the pin 202, a void (i.e., no welding flux) is easily formed in a region where the recess portion A is located during the transfer of welding flux to the pad. The inventors found that the larger a proportion of an area of an orthographic projection of the end face of the recess portion A close to the functional layer 201 on the functional layer 201 to an area of an orthographic projection of the pin 202 on the functional layer 201 (hereinafter referred to as “an arch bridge proportion” for short), the easier a void is formed.

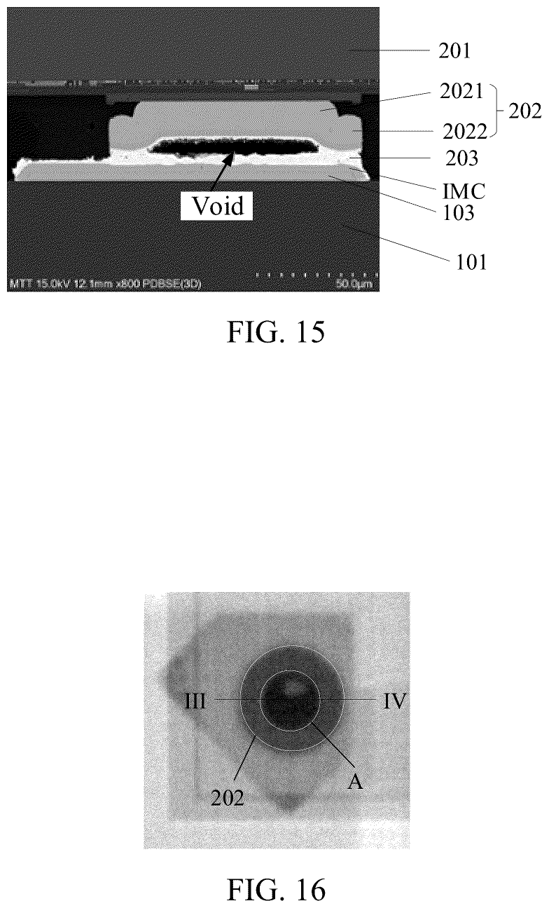

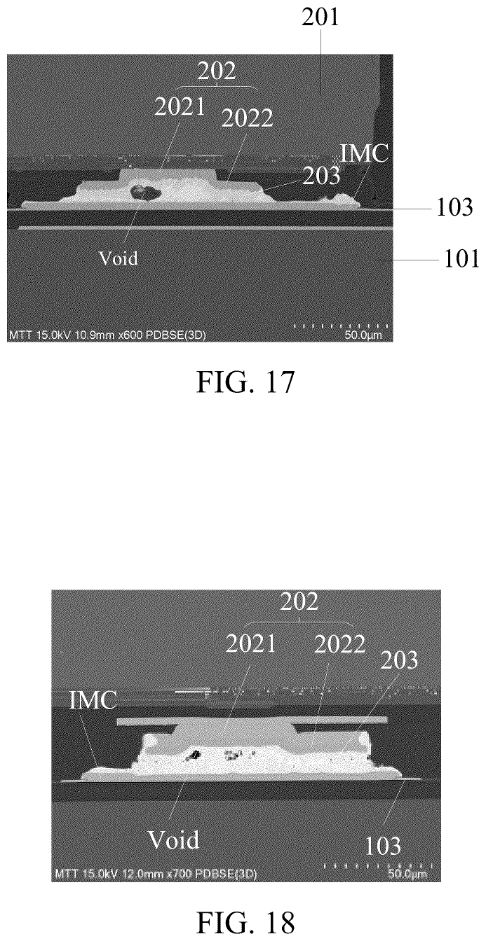

The inventors analyzed the welding behavior of electronic elements designed for different pins 202 (the difference mainly lies in the proportion and position of the arch bridge), and the results are shown in FIGS. 14 to 18. In FIGS. 14 to 18, that both the orthographic projection of the pin 202 and the orthographic projection of the end face of the recess portion A close to the functional layer 201 are circular is taken as an example for illustration. Exemplarily, in FIGS. 14 and 15, a big circle represents a profile of an orthographic of the pin 202, and a small circle represents a profile of an orthographic of an end face of the recess portion A close to the functional layer 201. The big circle has a diameter of 100 μm, the small circle has a diameter of 65 μm. A center of the big circle coincides with a center of the small circle, the arch bridge proportion is about 42%, and the measured voidage is 20% to 50%. In FIGS. 16 and 17, the big circle represents an area of an orthographic projection of the pin 202, and the small circle represents an area of an orthographic projection of the end face of the recess portion A close to the functional layer 201. A diameter of the big circle is 90 μm, and a diameter of the small circle is 35 μm. The center of the big circle coincides with the center of the small circle, the arch bridge proportion is about 15%, and the measured voidage is less than 15%. In FIG. 18, a diameter of the orthographic projection of the pin 202 is 100 μm, and a diameter of the orthographic projection of the end face of recess portion A close to functional layer 201 is 45 μm. A center of the orthographic projection of recess portion A is offset by 10 μm relative to an center of the orthographic projection of the pin 202, the arch bridge proportion is about 20%, and the measured voidage is less than 15%.

It can be seen from FIG. 14 to FIG. 18 that there is a strong correlation between the arch bridge proportion and the voidage, which shows that the larger the arch bridge proportion, the higher the voidage of welding, the smaller the arch bridge proportion, the smaller the voidage and the more stable the welding. Therefore, by reducing the arch bridge proportion, the welding voidage may be effectively controlled to ensure the welding quality. However, the pin 202 has the function of current conduction, and if it is designed to be too small, it is easy to burn the line due to locally heating. In order to balance the voidage and the arch bridge proportion, on the basis that the size of the recess portion A cannot be changed, the arch bridge proportion may be reduced by increasing the size of pin 202. In order to explore the upper limit of the arch bridge design, industry voidage standards may be introduced, such as the voidage standard≤25% in the International Electronic Industry Connection Association (IPC), and the design specification of the arch bridge proportion may be formulated. That is, in this disclosure, a ratio of an area f² of an orthographic projection of an end face of the recess portion A close to the functional layer 201 on the functional layer 201 to an area e² of an orthographic projection of the pin 202 on the functional layer 201 (i.e., the arch bridge proportion) may be set to be less than or equal to 25% (IPC industry standard). If special welding requirements are encountered, the arch bridge proportion can be appropriately adjusted, and the arch bridge proportion may be controlled to be between 0% and 30% according to the general standard of the voidage.

With continued reference to FIGS. 14 to 18, the voidage is related to the position of the recess portion A relative to the pin 202. In the present disclosure, there is a first distance between the center of the orthographic projection of the recess portion A on the functional layer 201 and the center of the orthographic projection of the pin 202 on the functional layer 201. In order to reduce the voidage and improve the welding quality, a ratio of the first distance to the radial length of the pin 202 may be set to be less than 20%. For example, in FIG. 16 and FIG. 17, the first distance is 0 μm, the radial length of the pin 202 is 90 μm, the ratio of the first distance to the radial length of the pin 202 is 0, and the voidage is less than 15%. In FIG. 18, the first distance is 10 μm, the radial length of the pin 202 is 100 μm, the ratio of the first distance to the radial length of the pin 202 is 10%, and the voidage is less than 15%.

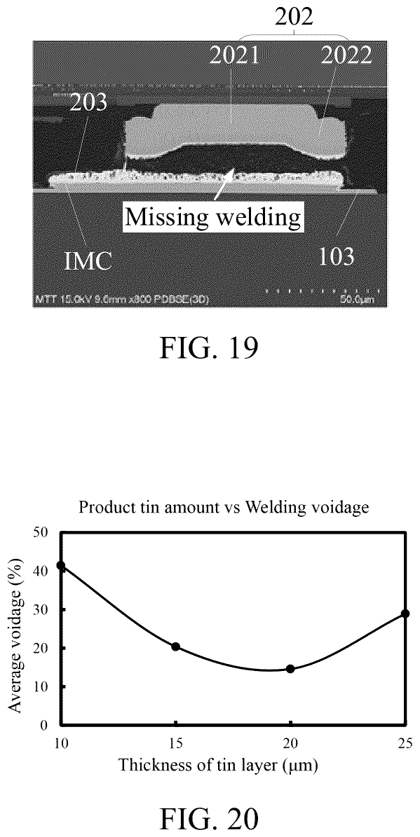

Considering that the design of the arch bridge pin 202 is easy to lose welding flux, all the welding flux on the pin 202 is transferred to the pad, resulting in an excessive voidage of arch bridge and even poor dewelding, as shown in FIG. 19; and therefore, the voidage may be improved by controlling the amount of welding flux. As shown in FIG. 20, through the welding verification of electronic elements with different thicknesses of welding flux layers, it is found that when the welding flux is less, for example, the welding flux layer thickness is less than or equal to 10 μm, a void is easily formed to the arch bridge due to the insufficient welding flux amount after the welding flux is transferred to the pad, resulting in high voidage; with the increase of the welding flux amount, the amount of transferable welding flux becomes more and the arch bridge is not easy to be completely emptied to form a large void, and at this time, the voidage decreases. However, with the further increase of the welding flux amount, the flux cannot be discharged from the welding flux in time due to the excessive welding flux amount, the flux residues and bubbles are easy to stay in the welding flux layer to form voids, and at this time, the voids tend to become large. Based on this, in the present disclosure, the thickness of the welding flux layer may be set in a range from 15 μm to 25 μm to ensure a low voidage. The welding flux layer may serve as a connection structure 203 at a side of the pin 202 away from the functional layer 201 in the electronic element shown in FIG. 13, so the thickness l of the connection structure 202 may be greater than or equal to 15 μm and less than or equal to 25 μm. Optionally, the connection structure 203 fills the recess portion A for electrically connecting the pins 202 with the pads 103 of the wiring substrate.

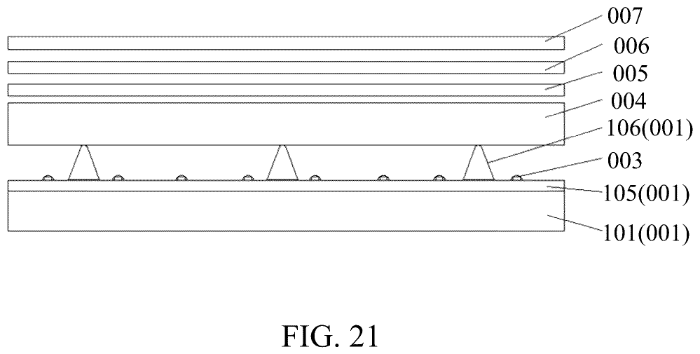

Based on the same inventive concept, an embodiment of the present disclosure provides an electronic apparatus, as shown in FIG. 21, including the aforementioned wiring substrate 001 according to an embodiment of the present disclosure and the above electronic elements (not shown in the figure) according to an embodiment of the present disclosure.

In some embodiments, as shown in FIG. 21, the electronic apparatus may further include a micro light emitting device 003 connected to the second pad group P2. Optionally, in a case that the electronic apparatus is used as a backlight apparatus, the electronic apparatus may also include a diffusion plate 004, a quantum dot film 005, a diffusion sheet 006 and a composite film 007 arranged sequentially at a light emitting side of the micro light emitting device 003, wherein the diffusion plate 004 and the diffusion sheet 006 are mainly for eliminating lamp shadows and improving picture uniformity, the composite film 007 is mainly for increasing brightness, and the quantum dot film 005 is excited by blue light to convert blue light into white light. The wiring substrate 001 mainly includes a base substrate, a connection line, a signal line, a first pad group P1 connected to the micro driver chip 002, a second pad group P2 connected to the micro light emitting device 003, a reflective layer 105 (for example, a white oil/reflective sheet), a dot compensation white glue, a protective glue (lens), a support post (supporter) 106, a circuit board (COF/PCB), and the like. The support post 106 may be fixed between the wiring substrate 001 and the diffusion plate 004 through glue or the like to support the diffusion plate 004 to obtain a certain light mixing distance and eliminate the lamp shadow.

In some embodiments, the wiring substrate according to the present disclosure may be used as the backplane of the miniLED direct display product, i.e. the optical films such as the diffusion plate 004, the quantum dot film 005, the diffusion sheet 006 and the composite film 007 are not included, and at this time, the micro light emitting device 003 including different light emitting colors of red (R), green (G) and blue (B) may be adopted, or the micro light emitting device 003 of the same color combined with the color conversion layer may be adopted to achieve color display.

Optionally, the electronic apparatus according to an present disclosure may be applied to display devices, lighting devices and the like, and in some embodiments, the display device may be any product or component with a display function, such as a projector, a 3D printer, a virtual reality device, a mobile phone, a tablet computer, a television, a display, a notebook computer, a digital photo frame, a navigator, a smart watch, a fitness wristband, a personal digital assistant, etc. The display device includes, but is not limited to, a radio frequency unit, a network module, an audio output and input unit, a sensor, a display unit, a user input unit, an interface unit, a control chip and other components. Optionally, the control chip is a central processing unit, a digital signal processor, a system-on-chip (SoC), and the like. For example, the control chip may also include a memory, a power supply module and the like, and may achieve power supply and signal input and output functions through conductive lines, and signal lines, etc., which are arranged additionally. For example, the control chip may also include hardware circuits, computer executable codes and the like. Hardware circuitry may include conventional very large scale integration (VLSI) circuitry or gate arrays as well as existing semiconductors such as logic chips, transistors or other discrete components; and hardware circuits may also include field programmable gate arrays, programmable array logic, programmable logic devices, and the like. In addition, it will be understood by those skilled in the art that the above structure is not a limitation on the display device provided in the embodiments of the present disclosure. In other words, the display device provided in the embodiments of the present disclosure may include more or less of the components described above, or some components combined, or different component arrangements.

Apparently, various modifications and variations to the embodiments of the present disclosure may be made by those skilled in the art without departing from the spirit and scope of the embodiments of the present disclosure. Thus, if these modifications and variations to the embodiments of the present disclosure fall within the scope of the claims of the present disclosure and their equivalent techniques, the present disclosure is intended to include these modifications and variations.

The invention claimed is:

1. A wiring substrate, comprising:
a base substrate;
connection lines located on the base substrate, wherein at least two of the connection lines are configured to transmit different signals;
a plurality of pads, wherein any two of the pads are distributed at intervals, and the pads comprise first pads; and
a first pad group composed of at least three of the first pads;
wherein the connection lines comprise a first type of connection line, and the first type of connection line comprises a plurality of branch portions, wherein different branch portions are connected with different first pads, and any two branch portions are arranged at intervals.

2. The wiring substrate according to claim 1, wherein the plurality of branch portions of a same first type of connection line extend along a same direction, and an extension length is at least 400 μm.

3. The wiring substrate according to claim 1, wherein the plurality of branch portions of a same first type of connection line and a plurality of the first pads respectively connected with the plurality of branch portions are arranged along a first direction, the plurality of branch portions extend along a second direction, and the first direction and the second direction have an included angle.

4. The wiring substrate according to claim 1, wherein the connection lines further comprise a second type of connection line, the second type of connection line is configured to connect two of the first pads in one of first pad groups, and an orthographic projection of the second type of connection line on the substrate is within an orthographic projection of a region wherein the first pad group is located on the substrate.

5. The wiring substrate according to claim 4, wherein two of the first pads connected by the second type of connection line are arranged along a first direction, and the second type of connection line extends along the first direction.

6. The wiring substrate according to claim 1, wherein the pads further comprise second pads, the wiring substrate further comprises a second pad group composed of two of the second pads, the connection lines further comprise a third type of connection line configured to be connected at least to one of the first pads, and a length of the third type of connection line is at least 400 μm.

7. The wiring substrate according to claim 1, wherein a difference between line widths of any connection line at various places is less than 15% in a direction perpendicular to an extension direction of the connection line.

8. The wiring substrate according to claim 7, wherein a difference between line widths of any two of the connection lines is less than 15% in a direction perpendicular to an extension direction of the connection lines.

9. The wiring substrate according to claim 1, wherein the wiring substrate further comprises signal lines, and each of the signal lines is coupled to at least one of the connection lines.

10. The wiring substrate according to claim 9, wherein a difference between a line width of a signal line in a direction perpendicular to an extension direction of the signal line and a line width of a connection line coupled to the signal line in a direction perpendicular to an extension direction of the connection line is less than 15%.

11. The wiring substrate according to claim 9, wherein the pads further comprise second pads, the wiring substrate further comprises a second pad group composed of two of the second pads, and the connection lines further comprise a fourth type of connection line, the fourth type of connection line is configured to connect one of the second pads with a signal line.

12. The wiring substrate according to claim 9, wherein a signal line and a connection lines coupled to the signal line are of an integral structure.

13. The wiring substrate according to claim 9, wherein any two adjacent branch portions corresponding to a same first pad group have a first spacing in a direction perpendicular to an extension direction of the branch portions, a minimum spacing between two adjacent signal lines is a second spacing, and a ratio of the first spacing to the second spacing is between 0.9 and 1.1.

14. An electronic element, wherein the electronic element is connected to a pad of the wiring substrate according to claim 1.

15. The electronic element according to claim 14, wherein the electronic element comprises a functional layer and a pin located on the functional layer, the pin comprises a recess portion arching towards the functional layer, the recess portion gradually decreases in a direction close to the functional layer, and a ratio of an area of an orthographic projection of an end face of the recess portion close to the functional layer on the functional layer to an area of an orthographic projection of the pin on the functional layer is less than or equal to 30%.

16. The electronic element according to claim 15, wherein there is a first distance between a center of an orthographic projection of the recess potion on the functional layer and a center of the orthographic projection of the pin on the functional layer, and a ratio of the first distance to a radial length of the pin is less than 20%.

17. The electronic element according to claim 15, wherein the electronic element further comprises a connection structure located at a side of the pin away from the functional layer, the connection structure fills the recess portion, and a thickness of the connection structure is greater than or equal to 15 μm and less than or equal to 25 μm.

18. The electronic element according to claim 14, wherein the electronic element comprises a micro driver chip, the micro driver chip is connected to the first pad group.

19. An electronic apparatus, comprising the wiring substrate according to claim 1 and an electronic element connected to a pad of the wiring substrate.

20. The electronic apparatus according to claim 19, further comprising a micro light emitting device connected to a second pad group.
